(19) United States
(12) Patent Application Publication
(10) Pub. No.: US 2017/0314157 A1
(43) Pub. Date: Nov. 2, 2017

(54) METHOD FOR MANUFACTURING NITRIDE CRYSTAL SUBSTRATE AND SUBSTRATE FOR CRYSTAL GROWTH

(71) Applicants: OSAKA UNIVERSITY, Suita-shi (JP); SCIOCS COMPANY LIMITED, Hitachi-shi (JP); SUMITOMO CHEMICAL COMPANY, LIMITED, Tokyo (JP)

(72) Inventors: Yusuke MORI, Suita-shi (JP); Masashi YOSHIMURA, Suita-shi (JP); Mamoru IMADE, Suita-shi (JP); Masayuki IMANISHI, Suita-shi (JP); Masatomo SHIBATA, Hitachi-shi (JP); Takehiro YOSHIDA, Hitachi-shi (JP)

(73) Assignees: OSAKA UNIVERSITY, Suita-shi (JP); SCIOCS COMPANY LIMITED, Hitachi-shi (JP); SUMITOMO CHEMICAL COMPANY, LIMITED, Tokyo (JP)

(21) Appl. No.: 15/584,756

(22) Filed: May 2, 2017

(30) Foreign Application Priority Data
May 2, 2016 (JP) 2016-092450

(51) Int. Cl. C30B 25/02; C30B 29/40

(52) U.S. Cl. CPC C30B 25/02; C30B 29/406

(57) ABSTRACT

A high-quality nitride crystal substrate is manufactured, using a substrate for crystal growth with its diameter enlarged, the nitride crystal substrate including: a first step of preparing a substrate for crystal growth having a plurality of seed crystal substrates made of nitride crystals, arranged in a planar appearance, so that their main surfaces are parallel to each other and their lateral surfaces are in contact with each other, and a difference of a lattice constant between adjacent seed crystal substrates arbitrarily selected from a plurality of the seed crystal substrates is within 7×10⁻⁵ Å; and a second step of growing a crystal film on a ground surface belonging to the substrate for crystal growth.

### BACKGROUND

### Technical Field

The present invention relates to a method for manufacturing a nitride crystal substrate and a substrate for crystal growth.

### Description of the Related Art

A substrate made of nitride crystals such as gallium nitride for example (referred to as a nitride crystal substrate hereafter), is used when manufacturing a semiconductor device such as a light-emitting element and a high-speed transistor. The nitride crystal substrate can be manufactured through the step of growing nitride crystals on a sapphire substrate or a substrate for crystal growth which is prepared using the sapphire substrate. In recent years, in order to obtain a nitride crystal substrate with a large diameter exceeding, for example, 2 inches, there is an increasing need for obtaining a substrate for crystal growth with a larger diameter (for example, see patent document 1).
Patent document 1: Japanese Patent Laid Open Publication No. 2006-290676

### SUMMARY OF THE INVENTION

An object of the present invention is to provide a technique capable of manufacturing a high-quality nitride crystal substrate, using a substrate for crystal growth with its diameter enlarged.

According to an aspect of the present invention, there is provided a technique, including:

a first step of preparing a substrate for crystal growth having a plurality of seed crystal substrates made of nitride crystals, arranged in a planar appearance, so that their main surfaces are parallel to each other and their lateral surfaces are in contact with each other, and a difference of a lattice constant between adjacent seed crystal substrates arbitrarily selected from a plurality of the seed crystal substrates is within 7×10⁻⁵ Å or a difference of an oxygen concentration between adjacent seed crystal substrates is within 9.9×10¹⁸ at/cm³; and

a second step of growing a crystal film on a ground surface belonging to the substrate for crystal growth.

According to other aspect of the present invention, there is provided a technique, including:

a first step of preparing a substrate for crystal growth having a plurality of seed crystal substrates made of nitride crystals, arranged in a planar appearance, so that their main surfaces are parallel to each other and their lateral surfaces are in contact with each other; and

a second step of growing a crystal film on a ground surface belonging to the substrate for crystal growth, wherein a difference of a lattice constant between the crystal film and a seed crystal substrate arbitrarily selected from a plurality of the seed crystal substrates is within 7×10⁻⁵ Å, or a difference of an oxygen concentration therebetween is within 9.9×10¹⁸ at/cm³.

According to the present invention, it is possible to provide a technique capable of manufacturing a high-quality nitride crystal substrate, using a substrate for crystal growth with its diameter enlarged.

### BRIEF DESCRIPTION OF THE DRAWINGS

FIG. 1A is a planar view of a small diameter seed substrate used when a seed crystal substrate is prepared, FIG. 1B is a planar view of the seed crystal substrate obtained from the small diameter seed substrate, and FIG. 1C is a lateral view of the seed crystal substrate.

FIG. 2A is a planar view showing an example of an arrangement pattern of the seed crystal substrates, and FIG. 2B is a cross-sectional view taken along line B-B′ of a group of the seed crystal substrates shown in FIG. 2A.

FIG. 3 is a schematic view of a vapor-phase growth apparatus used when growing a first crystal film and a third crystal film.

FIG. 4A is a cross-sectional view of a combined substrate obtained by vapor-phase growing the first crystal film on the seed crystal substrates, and FIG. 4B is an expanded cross-sectional view showing a state in which a V-groove is formed on a main surface of the combined substrate.

FIG. 5 is a schematic configuration view of a liquid-phase growth apparatus used when growing a second crystal film.

FIG. 6A is a cross-sectional view of a substrate for crystal growth obtained by liquid-phase growing the second crystal film on the combined substrate, FIG. 6B is an expanded cross-sectional view showing a state in which a main surface of the substrate for crystal growth is smoothed by embedding the second crystal film in the V-groove, and FIG. 6C is a pattern diagram showing a case in which a portion having a desired impurity concentration is cut out from the second crystal film, and the cutout portion is used as the substrate for crystal growth.

FIG. 7A is a cross-sectional configuration view showing a state in which the third crystal film is vapor-phase grown on the main surface of the substrate for crystal growth, and FIG. 7B is a pattern diagram showing a state in which a plurality of nitride crystal substrates are obtained by cutting out from the third crystal film.

FIG. 8A is an expanded cross-sectional view showing an example of crystal growth on an interface, FIG. 8B is an expanded cross-sectional view showing a modified example of crystal growth on the interface, and FIG. 8C is an expanded cross-sectional view showing a modified example of crystal growth on the interface.

FIG. 9A is a view showing an O concentration dependence of a lattice constant in a nitride crystal by a logarithmic graph, and FIG. 9B is a view showing the O concentration dependence of the lattice constant in the nitride crystal by a linear scale.

FIG. 10A to FIG. 10C are photographs showing a state in which nitride crystal is grown on the seed crystal substrates respectively.

### DETAILED DESCRIPTION OF THE INVENTION

### An Embodiment of the Present Invention

An embodiment of the present invention will be described hereafter, with reference to the drawings.

### (1) Method for Manufacturing a Nitride Crystal Substrate

In this embodiment, explanation is given for an example of manufacturing a crystal substrate made of gallium nitride (GaN) crystals (also referred to as a GaN substrate hereafter), as a nitride crystal substrate, by performing steps 1 to 6 shown below.

### (Step 1: Preparation of Seed Crystal Substrates)

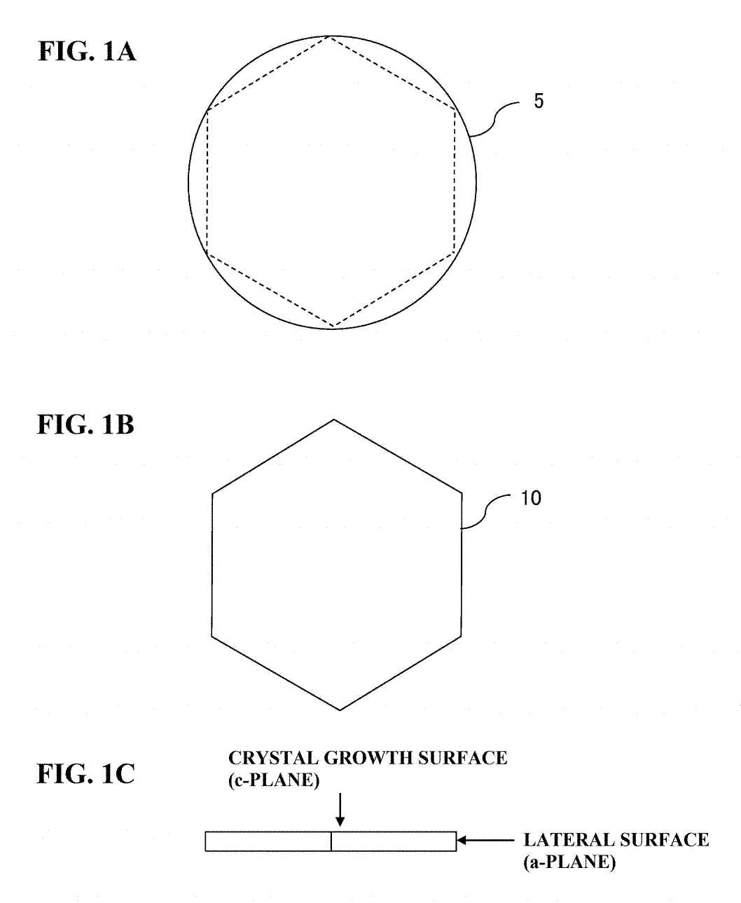

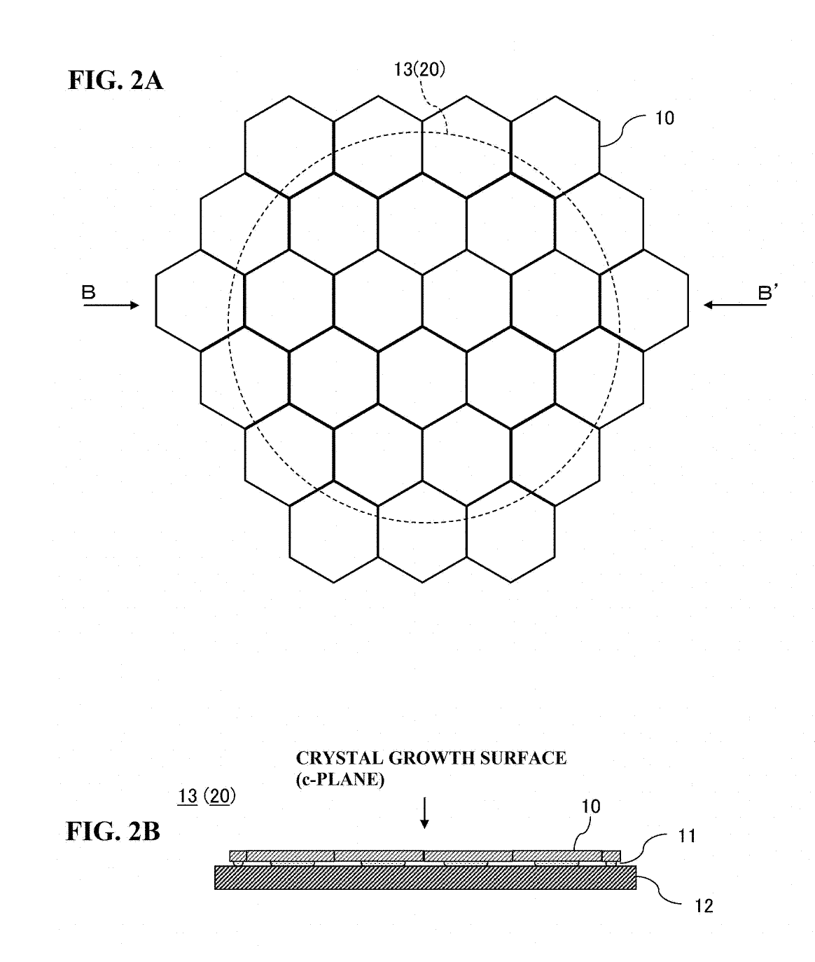

In this embodiment, when the GaN substrate is manufactured, a substrate for crystal growth 20 (also referred to as a substrate 20 hereafter) having an outer shape as exemplified by a broken line in FIG. 2A is used. In this step, first, a plurality of small diameter seed substrates (crystal substrates) 5 (also referred to as a substrate 5 hereafter) made of GaN crystals and whose outer shape is shown by a solid line in FIG. 1A, are prepared as a base material used when seed crystal substrates 10 (also referred to as substrates 10) constituting the substrate 20 are prepared. Each substrate 5 is a circular substrate having an outer diameter larger than each outer diameter of the substrates 10 to be prepared, and for example, can be prepared by epitaxially growing GaN crystals on a ground substrate such as a sapphire substrate, and cutting out grown crystals from the ground substrate and polishing the surface of the crystals. GaN crystals can be grown using a publicly-known technique, irrespective of a vapor-phase growth method or a liquid-phase growth method. According to a current state of the art, in a case that a diameter of the substrate is about 2 inches, a high-quality substrate can be obtained at a relatively low cost, with a low defect density and a low impurity concentration, in which a variation of an off-angle, namely, a difference between a maximum value and a minimum value of the off-angle in its main surface (base surface for crystal growth), is for example 0.3° or less and relatively small. Here, the off-angle is defined as the angle between a normal line direction of the main surface of the substrate 5, and a main axis direction (the normal line direction of a low index plane closest to the main surface) of GaN crystals constituting the substrate 5.

In this embodiment, as an example, explanation is given for a case of using a substrate with diameter D of about 2 inches and thickness T of 0.2 to 1.0 mm as the substrate 5. Further, in this embodiment, explanation is given for the following case: a substrate in which the main surface, namely, a crystal growth surface of the substrate 5 is parallel to c-plane of GaN crystal, or having an inclination within ±5°, preferably within ±1° with respect to c-plane, is used as the substrate 5. Further, in this embodiment, explanation is given for the following example: when a plurality of substrates 5 are prepared, a group of substrates in which the variation of the off-angle (difference between the maximum value and the minimum value of the off-angle) in the main surface of a plurality of substrates 5 is 0.3° or less and preferably 0.15° or less, and the variation of the off-angle (difference between the maximum value and the minimum value of the off-angle) among a plurality of substrates 5 is 0.3° or less and preferably 0.15° or less, is used as a plurality of substrates 5.

The term of “c-plane” used in this specification can include not only the c-plane of GaN crystal, namely, a plane completely parallel to (0001) plane, but also a plane having a certain degree of inclination (vicinal) with respect to (0001) plane as described above. This point is also applied to a case of using the term of “a-plane” and “M-plane” in this specification. Namely, the term of “a-plane” used in this specification can include not only the a-plane of GaN crystal, namely, a plane completely parallel to (11-20) plane, but also a plane having the similar inclination as the above inclination to this plane. Also, the term of “M-plane” used in this specification can include not only the M-plane of GaN crystal, namely, a plane completely parallel to (10-10) plane, but also a plane having the similar inclination as the above inclination to this plane.

In this embodiment, when a plurality of substrates 5 are prepared, each substrate is respectively selected so that a difference of a lattice constant among the substrates 5 is a predetermined range within 7×10⁻⁵ Å, preferably within 2×10⁻⁵ Å. The “lattice constant of the substrate 5” mentioned here means “the lattice constant in a-axis direction (direction parallel to a-axis) of GaN crystal constituting the substrate 5”. In this embodiment, when a plurality of substrates 5 are prepared, it is necessary to select each substrate so that the difference of the lattice constant in the a-axis direction between adjacent substrates 10 satisfies the abovementioned requirements, even when a main surface (crystal growth surface) of the substrate 10 obtained by processing the substrate 5 is set as c-plane, and as described later, and even when a lateral surface (combining surface) of the substrate 10 is set as a-plane or M-plane.

Further, in this embodiment, when a plurality of substrates 5 are prepared, predetermined requirements are also imposed on an oxygen (O) concentration among the substrates 5. The “O concentration of the substrate 5” mentioned here means “the O concentration of GaN crystal constituting the substrate 5” in the same manner as described above, and in addition, it means “the O concentration of GaN crystal constituting the main surface and the lateral surface of the substrate 10 obtained by processing the substrate 5”.

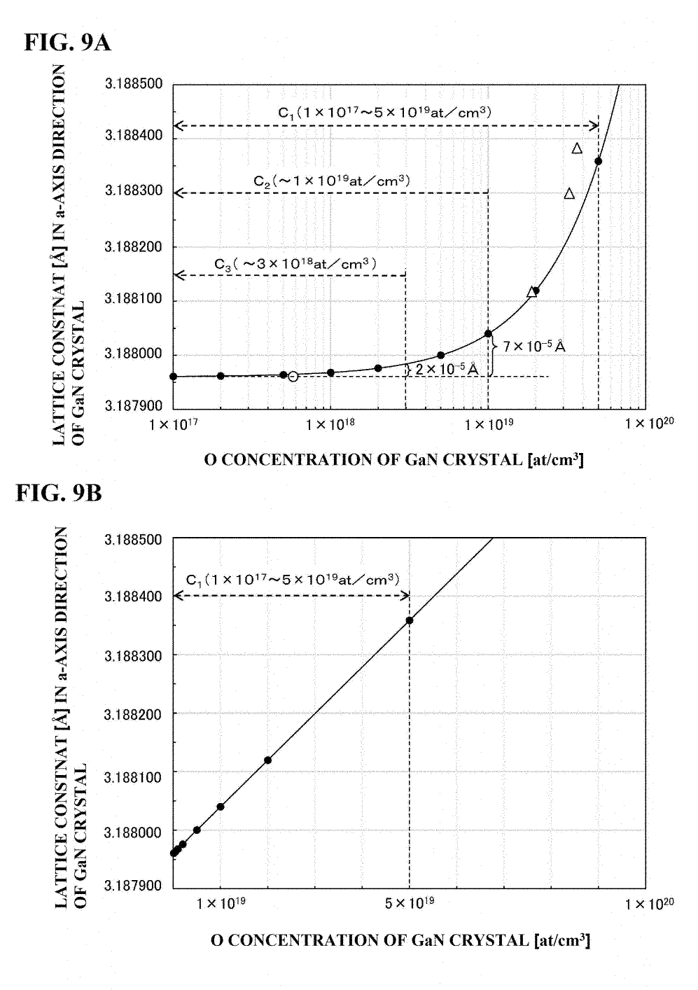

The reason for imposing the predetermined requirements on the O concentration is that O which is supposed to be contained in GaN crystal acts as a factor for increasing the lattice constant of GaN crystal. FIG. 9A and FIG. 9B show a relationship between the lattice constant and the O concentration in GaN crystal. The vertical axes in these figures indicate lattice constants [Å] in the a-axis direction of GaN crystal, respectively. Further, a horizontal axis of FIG. 9A shows the O concentration [at/cm³] of GaN crystal on a logarithmic scale and a horizontal axis of FIG. 9B shows the O concentration [at/cm³] of GaN crystal on a linear scale, respectively. Solid lines in these figures show simulation results of the lattice constants calculated based on a theoretical equation reported in C. G. Van de Walle, Phys. Rev. B 68 (2003) 165209, respectively. Further, in FIG. 9A, symbols ◯ and Δ indicate actual measurement values respectively. Symbol ◯ indicates the actual measurement value of the O concentration in a case that GaN crystal is grown toward a direction (c-plane direction) in which incorporation of O into the crystal is relatively small, and symbol Δ indicates the actual measurement value of the O concentration in a case that GaN crystal is grown toward a direction (M-plane direction) in which incorporation of O into the crystal is relatively large.

According to these figures, when the O concentration of GaN crystal is set to a predetermined range within at least a range of 1×10¹⁷ to 5×10¹⁹ at/cm³ (a range indicated by C₁ in these figures), it is found that the lattice constant of GaN crystal varies linearly, with a variation of the O concentration, namely, the lattice constant of GaN crystal is increased proportionally, according to an increase of the O concentration. Then, according to these figures, it is found that when the O concentration of each of a plurality of substrates 5 is set to the concentration at least within the abovementioned range C₁, it is possible to suppress the difference of the lattice constant among the substrates 5 to a range within 7×10⁻⁵ Å, by setting the difference of the O concentration (difference of the number of O contained per unit volume) among the substrates 5 within a range of, for example, 9.9×10¹⁸ at/cm³ (=1×10¹⁹-1×10¹⁷ at/cm³). Further, according to these figures, it is found that when the O concentration of each of a plurality of substrates 5 is set to the concentration within the abovementioned range C₁, it is possible to suppress the difference of the lattice constant among the substrates 5 to a range within 2×10⁻⁵ Å, by setting the difference of the O concentration among the substrates 5 within a range of, for example, 2.9×10¹⁸ (=3×10¹⁸-1×10¹⁷ at/cm³).

Further, according to these figures, when the O concentration of each of a plurality of substrates 5 is set to the concentration, for example within a range of 1×10¹⁹ at/cm³ or less (a range indicated by C₂ in FIG. 9A), it is found that the difference of the lattice constant among the substrates 5 is inevitably within a range of 7×10⁻⁵ Å, even when the difference of the O concentration among the substrates 5 exceeds 9.9×10¹⁸ at/cm³. Further, according to these figures, when the O concentration of each of a plurality of substrates 5 is set to the concentration, for example within a range of 3×10¹⁸ at/cm³ or less (a range indicated by C₃ in FIG. 9A), it is found that the difference of the lattice constant among the substrates 5 is inevitably within a range of 2×10⁻⁵ Å, even when the difference of the O concentration among the substrates 5 exceeds 2.9×10¹⁸ at/cm³.

In consideration of O concentration dependence of the lattice constant described above, in this embodiment, when a plurality of substrates 5 are prepared, each substrate 5 is selected so that the difference of the O concentration among the substrates 5 is set to a predetermined range of for example within 9.9×10¹⁸ at/cm³, preferably within 2.9×10¹⁸ at/cm³. Thereby, the difference of the lattice constant among a plurality of substrates 5, that is, the difference of the lattice constant among the substrates 10 obtained by processing these substrates 5, can be suppressed to a predetermined range of for example within 7×10⁻⁵ Å, preferably within 2×10⁻⁵ Å.

Further, according to this embodiment, when a plurality of substrates 5 are prepared, each substrate can also be selected so that the O concentration of each substrate 5 is set to a predetermined concentration for example within a range of 1×10¹⁹ at/cm³ or less, preferably 3×10¹⁸ at/cm³ or less. When the O concentration of each of the substrates 5 is set as described above, it can be surely performed that the difference of the lattice constant among the substrates 5, that is, the difference of the lattice constant among the substrates 10 obtained by processing these substrates 5 is set to a predetermined range for example within 7×10⁻⁵ Å, preferably within 2×10⁻⁵ Å, even in a case that the difference of the O concentration among the substrates 5 exceeds 9.9×10¹⁸ at/cm³.

In this manner, according to this embodiment, when a plurality of substrates 5 are prepared, predetermined requirements are imposed on the difference of the lattice constant or the difference of the O concentration, respectively. The upper limit of the difference of the lattice constant and the upper limit of the difference of the O concentration are described here, but there is no particular limit in lower limits of them, and it is preferable that the lower limits are zero, namely, there is no difference in the lattice constant and the O concentration among a plurality of substrates 5. However, O is inevitably mixed in the growth process of GaN crystal, and therefore it is difficult to precisely control its concentration, and it is common that the difference of the O concentration of, for example, about 0.1×10¹⁸ at/cm³ occurs among a plurality of substrates 5. For this reason, it is also difficult to set the difference of the lattice constant to zero among a plurality of substrates 5, and it is also common that the difference of the lattice constant of, for example, about 0.1×10⁻⁵ Å occurs.

After the substrate 5 is prepared, a substrate 10 is obtained by removing a circumferential edge portion of the substrate 5, as shown in a planar configuration in FIG. 1B, and as shown in a lateral configuration in FIG. 1C. When a plurality of substrates 10 are arranged on the same plane, a planar shape of the substrates 10 is preferably a shape capable of forming a tessellation, that is, they can be laid over the entire in-plane area without gaps. In a case that the main surface (crystal growth surface) of the substrate 10 is set as c-plane as in this embodiment, for the reason described later, it is preferable that all lateral surfaces of the substrates 10 in contact with the lateral surfaces of other substrates 10, namely, all surfaces opposed to (facing) the lateral surfaces of other substrates 10 are M-plane or a-plane, and are the planes in the same orientation each other (equivalent planes). The planar shape of each substrate 10 is preferably an equilateral triangle, a parallelogram, a trapezoid, or a regular hexagon, or the like. If the planar shape of the substrate 10 is a square or a rectangle, the following case occurs: when any one of the lateral surfaces of the substrates 10 is a-plane, the lateral surface orthogonal to this lateral surface inevitably becomes M-plane, thus making it impossible to be the planes in the same orientation each other. If the planar shape of the substrate 10 is circular or elliptical, the tessellation is impossible, and the lateral surface of the substrate 10 cannot be M-plane or a-plane, and cannot be the planes in the same orientation each other.

### (Step 2: Arrangement of the Seed Crystal Substrates)

When a plurality of substrates 10 are obtained, step 2 is performed. In this step, a plurality of substrates 10 made of GaN crystals are arranged in a planar appearance (tessellation), so that their main surfaces are parallel to each other and their lateral surfaces are in contact with each other.

As described above, in step 1, when a plurality of substrates 5 are prepared as base materials of the substrates 10, various requirements are imposed on these lattice constant and O concentration. As a result, the lattice constant and the O concentration also become uniform among a plurality of substrates 10 arranged in step 2. Specifically, the difference of the lattice constant between adjacent substrates 10 arbitrarily selected from a plurality of substrates 10 is within 7×10⁻⁵ Å, preferably within 2×10⁻⁵ Å, and the difference of the O concentration therebetween is within 9.9×10¹⁸ at/cm³, preferably within 2.9×10¹⁸ at/cm³.

The description: “a plurality of substrates 10 are arranged so that their main surfaces are parallel to each other” includes not only a case in which the main surfaces of adjacent substrates 10 are arranged completely in the same surface, but also a case in which there is a slight difference in the heights of these surfaces and a case in which these surfaces are arranged with a slight inclination with respect to each other. Namely, this description shows a case in which a plurality of substrates 10 are arranged so that the main surfaces of them are arranged in the same heights and in parallel to each other as much as possible. However, even in a case that there are differences in the heights of the main surfaces of adjacent substrates 10, the size of each difference is preferably set to for example 100 μm or less at largest, and more preferably set to 50 μm or less. Further, even in a case that an inclination occurs in the main surfaces of adjacent substrates 10, the size of the inclination is preferably set to for example 1° or less in the largest surface and more preferably set to 0.5° or less. Further, when a plurality of substrates 10 are arranged, the variation of the off-angle in the main surface (difference between a maximum value and a minimum value of the off-angle in the entire main surface) of the group of substrates obtained by arranging a plurality of substrates 10, is preferably set to for example 0.3° or less, and more preferably set to 0.15° or less. This is because if these variations are too large, there is sometimes a possibility of deteriorating the quality of the crystal grown in steps 3, 5 and 6 described later.

Further, the description: “a plurality of substrates 10 are arranged so that their lateral surfaces are in contact with each other” means a case in which a plurality of substrates 10 are arranged so as to be opposed in proximity to each other and not to allow the gap to occur between the lateral surfaces of them. Namely, this description includes not only a case in which the lateral surfaces of adjacent substrates 10 are completely in contact with each other without gaps, but also a case in which there are slight gaps between them. However, if the gap is too large, there is a case in which adjacent substrates 10 are not combined, or even in a case that they are combined, a strength of combining them is insufficient, when step 3 (crystal growth step) described later is performed. Therefore, it is desirable that the gap is not allowed to occur as much as possible.

FIG. 2A is a planar view showing an example of an arrangement pattern of the substrates 10. When the substrate 20 whose planar shape is a circular shape is prepared, with its outer shape shown by a broken line in FIG. 2A, a circumferential edge portion (portion outside of the broken line) of the substrate 10 (substrate 10 that intersect with the broken line) constituting the circumferential edge portion of the substrate 20, may be cut into an arc shape according to the outer shape of the substrate 20. Such a cutting processing may be performed before the substrates 10 are assembled, or may be performed after assembly.

As shown in FIG. 2A, it is found that the substrate 10 arbitrarily selected from a plurality of the arranged substrates 10 is configured to be in contact with at least two or more other substrates 10. It is also found that two or more contact surfaces of this arbitrarily selected substrate 10 are configured not to be orthogonal to each other. It can be said that such a situation is unique obtained when for example a regular hexagon, an equilateral triangle, a parallelogram, or a trapezoid is selected as the planar shape of the substrate 10, and a plurality of substrates 10 are tessellated in approximately circular shape (not only in one direction but also in many directions) as shown in this figure. Further, as shown in this figure, it is also found that a plurality of substrates 10 are mutually engaged (combined) with each other in planar view, and they are arranged so as to make it difficult for an arrangement misalignment to occur in the substrates 10 in the step 3 and subsequent steps. It can be said that such a situation is unique obtained when the planar shape of the substrate 10 is a regular hexagon, and a plurality of substrates 10 are tessellated in approximately circular shape as shown in this figure.

In order to facilitate handling in step 3 described later, a plurality of substrates 10 are preferably fixed, for example on a holding plate (support plate) 12 formed as a flat plate. FIG. 2B shows a cross-sectional configuration of an assembled substrate 13 formed by adhering a plurality of substrates 10 to the holding plate 12 using an adhesive agent 11. As shown in this figure, the substrates 10 are placed on the holding plate 12 so that their main surfaces (crystal growth surfaces) are faced upward. The holding plate 12 and the adhesive agent 11 preferably have a heat resistance that withstands a film-forming temperature in a vapor-phase growth processing of step 3 described later. Fixation of the substrates 10 is not limited to the abovementioned method, and may be performed using a fixing jig, etc.

The assembled substrate 13, namely, the assembled substrate 13 in a state before forming a GaN crystal film 14 (also referred to as a GaN film 14 hereafter) described later, can be considered as one of the modes of the substrate 20 in this embodiment. Namely, a plurality of GaN substrates 30 may be obtained by thickly growing a GaN crystal film 21 (also referred to as a GaN film 21 hereafter) described later on the main surface (crystal growth surface) of the assembled substrate 13 obtained here, using a hydride vapor-phase epitaxy (HVPE) method or the like, and slicing such a thickly grown GaN film 21. However, it is preferable to perform step 3 (vapor-phase growth step) described later, to thereby prepare a freestandable combined substrate 15, formed by combining a plurality of substrates 10 by the GaN film 14, and use the prepared combined substrate 15 as the substrate 20, in terms of reliably of preventing positional misalignment or the like of the substrate 10 and facilitating its handling.

### (Step 3: Combination by Vapor-Phase Growth)

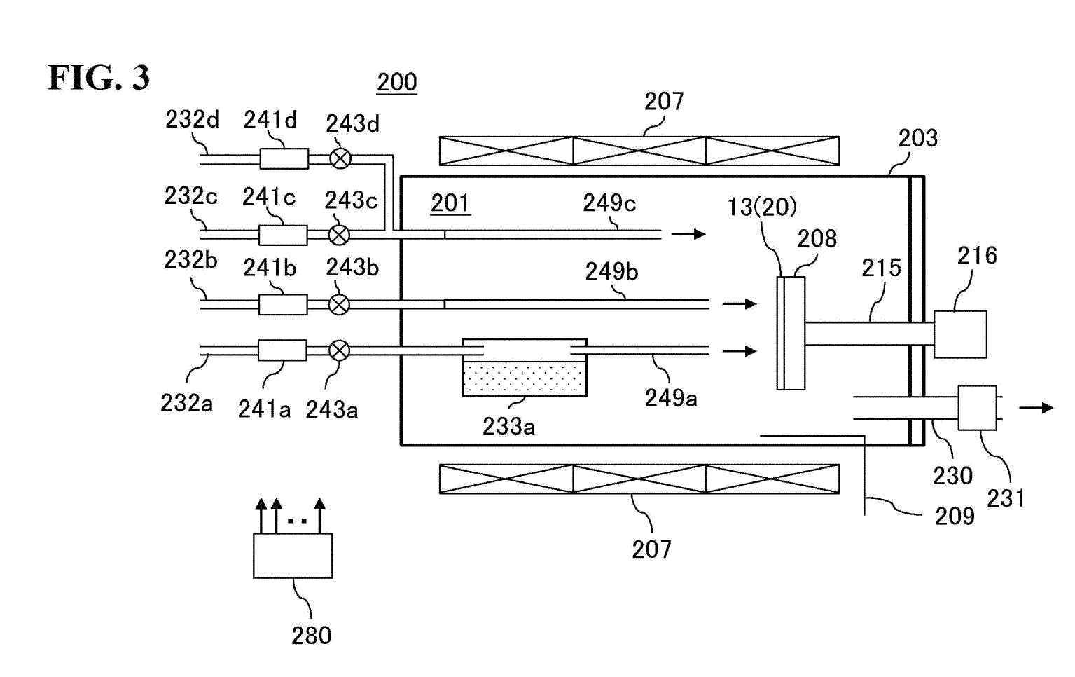

When the adhesive agent 11 is solidified and preparation of the assembled substrate 13 is completed, the GaN film 14 as a first crystal film (thin film for combination) is grown on the surface of a plurality of substrates 10 arranged in a planar appearance, using a HVPE apparatus 200 shown in FIG. 3.

The HVPE apparatus 200 is made of a heat-resistant material such as quartz, and includes an airtight container 203 having a film-forming chamber 201 formed therein. A susceptor 208 for holding the assembled substrate 13 and the substrate 20, is provided in the film-forming chamber 201. The susceptor 208 is connected to a rotating shaft 215 provided in a rotation mechanism 216, and configured to be rotatable. Gas supply pipes 232a to 232c for supplying hydrochloric acid (HCl) gas, ammonia (NH₃) gas, and nitrogen (N₂) gas into the film-forming chamber 201, is connected to one end of the airtight container 203. A gas supply pipe 232d for supplying hydrogen (H₂) gas is connected to the gas supply pipe 232c. Flow rate controllers 241a to 241d, and valves 243a to 243d are respectively provided on the gas supply pipes 232a to 232d sequentially from an upstream side. A gas generator 233a for containing Ga melt as a raw material, is provided on a downstream side of the gas supply pipe 232a. A nozzle 249a for supplying gallium chloride (GaCl) gas generated by a reaction between HCl gas and the Ga melt toward the assembled substrate 13, etc., held on the susceptor 208, is connected to the gas generator 233a. Nozzles 249b and 249c for supplying various gases supplied from gas supply pipes 232b and 232c toward the assembled substrate 13, etc., held on the susceptor 208, are respectively connected to the downstream side of the gas supply pipes 232b and 232c. An exhaust pipe 230 for exhausting inside of the film-forming chamber 201, is provided on the other end of the airtight container 203. A pump 231 is provided to the exhaust pipe 230. A zone heater 207 for heating inside of the gas generator 233a and the assembled substrate 13, etc., held on the susceptor 208, to a desired temperature, is provided on an outer periphery of the airtight container 203, and a temperature sensor 209 for measuring a temperature of the inside of the film-forming chamber 201 is provided in the airtight container 203, respectively. Each member provided in the HVPE apparatus 200, is connected to a controller 280 configured as a computer, and is configured to control processing procedures and processing conditions described later, based on a program executed by the controller 280.

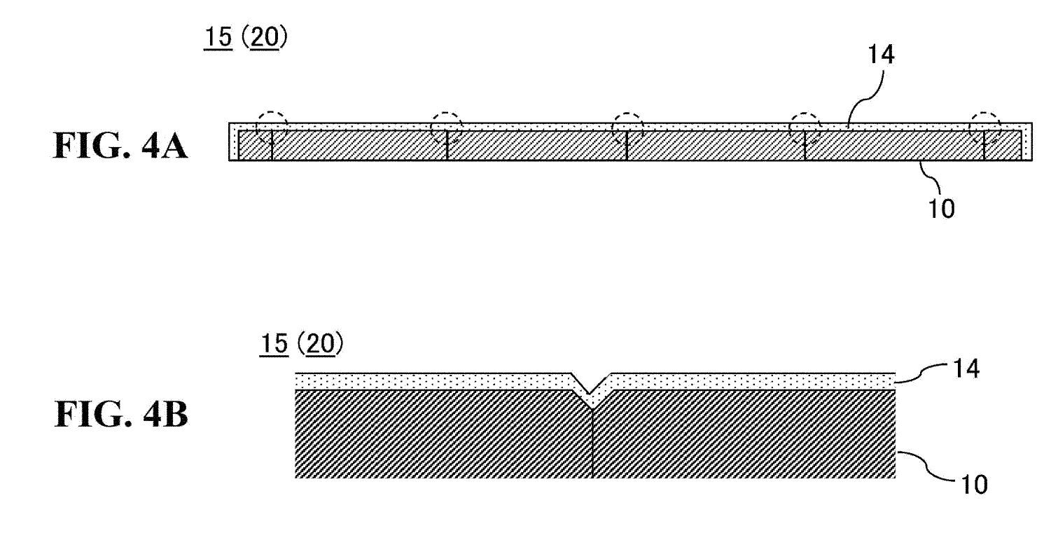

Step 3 can be performed using the abovementioned HVPE apparatus 200, for example based on the following processing procedures. First, Ga melt as a raw material is put in the gas generator 233a, and the assembled substrate 13 is placed on the susceptor 208. Then, H₂ gas (or mixed gas of H₂ gas and N₂ gas) is supplied into the film-forming chamber 201, while executing heating and exhausting the inside of the film-forming chamber 201. Then, gas supply is performed from the gas supply pipes 232a and 232b in a state in which the inside of the film-forming chamber 201 is set in a desired film-forming temperature and in a desired film-forming pressure, and in a state in which the inside of the film-forming chamber 201 is set in a desired atmosphere, and GaCl gas and NH₃ gas, which are film-forming gases, are supplied to the main surface of the assembled substrate 13 (substrates 10). Thus, as shown in the cross-sectional view of FIG. 4A, GaN crystal is epitaxially grown on the surface of the substrates 10, and the GaN film 14 is formed thereon. Owing to the formation of the GaN film 14, adjacent substrates 10 are combined with each other by the GaN film 14, and formed into an integral state. In order to prevent decomposition of the crystals constituting the substrates 10 in the film-formation processing, NH₃ gas is preferably supplied prior to HCl gas (for example before heating the inside of the film-forming chamber 201). Further, in order to increase in-plane uniformity of a film thickness of the GaN film 14 and increase the combining strength between adjacent substrates 10 evenly in the in-plane area, step 3 is preferably performed in a state of rotating the susceptor 208.

Step 3 is performed based on the following processing conditions for example:

Film-forming temperature (temperature of the assembled substrate): 980 to 1100° C., and preferably 1050 to 1100° C.

Film-forming pressure (pressure in the film-forming chamber): 90 to 105 kPa, and preferably 90 to 95 kPa

Partial pressure of GaCl gas: 1.5 to 15 kPa

Partial pressure of NH₃ gas/Partial pressure of GaCl gas: 2 to 6

Flow rate of N₂ gas/Flow rate of H₂ gas: 1 to 20

By growing the GaN film 14 under the abovementioned conditions, adjacent substrates 10 are in a state in which they are combined with each other. As described above, in this embodiment, the predetermined requirements are imposed on the difference of the lattice constant and the difference of the O concentration between adjacent substrates 10, respectively. Thereby, it is possible to improve the quality of the GaN film 14 to be grown at a combined part between adjacent substrates 10. As a result, it is possible to increase the combining strength between adjacent substrates 10.

Further, in this embodiment, the predetermined requirements are imposed on the difference of the lattice constant and the difference of the O concentration between the substrate 10 and the GaN film 14 as well. Specifically, the GaN film 14 is grown under a condition such that a difference between the lattice constant of the substrate 10 arbitrarily selected from a plurality of substrates 10, and the lattice constant of the GaN film 14 formed thereon is for example within 7×10⁻⁵ Å, preferably within 2×10⁻⁵ Å. Further, specifically the GaN film 14 is grown under a condition such that a difference between the O concentration of the substrate 10 arbitrarily selected from a plurality of substrates 10, and the O concentration of the GaN film 14 formed thereon is for example within 9.9×10¹⁸ at/cm³, preferably within 2.9×10¹⁸ at/cm³.

Thereby, the quality of the GaN film 14 grown on the substrates 10 can be improved. As a result, the combining strength between adjacent substrates 10 can be further increased. The lattice constant and the O concentration of the GaN film 14 can be controlled by adjusting the growth conditions, for example, O₂ partial pressure in the atmosphere of the film-forming chamber 201, H₂ partial pressure therein, a total pressure in the film-forming chamber 201, a growth temperature, and a growth rate, etc.

In this manner, according to this embodiment, predetermined requirements are imposed on the difference of the lattice constant and the difference of the O concentration not only between adjacent substrates 10 but also between the substrate 10 and the GaN film 14. In the same manner as described above, there is no particular limit in lower limits of them, and it is preferable that the lower limits are zero. However, O is inevitably mixed also in the growth process of the GaN film 14, and therefore it is difficult to precisely control its concentration, and it is common that the difference of the O concentration of, for example, about 0.1×10¹⁸ at/cm³ occurs, or the difference of the lattice constant of, for example, about 0.1×10⁻⁵ Å occurs between the substrate 10 and the GaN film 14.

As described above, by growing the GaN film 14, it is possible to obtain the freestandable combined substrate 15 by combining adjacent substrates 10 each other. The combined substrate 15 can also be considered as one of the modes of the substrate 20 in this embodiment. Namely, a plurality of GaN substrates 30 may be obtained by thickly growing the GaN film 21 described later on the main surface (crystal growth surface) of the combined substrate 15 obtained here, using the HVPE method, etc., and slicing the thickly grown GaN film 21.

However, the surface of the GaN film 14 constituting a main surface of the combined substrate 15 cannot be completely a smooth surface, and for example a V-shaped groove portion in cross-section (the groove portion is also referred to as V-groove hereafter) is sometimes formed on its surface. Since this V-groove sometimes adversely affects the quality of GaN crystal grown thereon, it is preferable to make it disappear as much as possible. Therefore, in this embodiment, step 5 (liquid-phase growth step) is performed as will be described later to make the V-groove disappear. By performing step 5, not only making the V-groove disappear but also an effect of reducing a screw dislocation density of GaN crystal grown thereon can be obtained. As described above, the liquid-phase growth step of step 5 can be omitted when priority is put on simplifying the manufacturing steps of the GaN substrate 30. However, it is preferable to perform the liquid-phase growth step, from a viewpoint of improving the quality of the GaN substrate 30.

For reference, FIG. 4B shows a state in which the V-groove is formed on the surface of the GaN film 14. FIG. 4B is a partially expanded view of an area indicated by a broken line of FIG. 4A. The V-groove is completely different from a so-called “pit” which is temporarily generated during a crystal growth, in a point that it is formed under an influence of the combined part of the substrates 10, and it is difficult to be made to disappear even though the vapor-phase growth is continued for a long time in step 3. The pit is temporarily generated due to locally different crystal growth rates under an influence of a ground surface condition, and even if the pit is generated, it can disappear by continuing the vapor-phase growth thereafter. In contrast, the V-groove is generated due to a difference in crystal growth directions at the combined part of the substrates 10, and a generation mechanism of the V-groove is completely different from that of the pit, and even if the vapor-phase growth is continued, it is difficult to make the V-groove disappear unlike the pit.

Thus, in step 3, when the V-groove is formed on the surface of the GaN film 14, it is difficult to make the V-groove disappear, namely, it is difficult to completely smoothen the upper surface of the combined part, even if the vapor-phase growth is continued for a long time. Therefore, when performing step 5 (liquid-phase growth step) described later for the purpose of making the V-groove disappear, the vapor-phase growth is preferably performed in step 3 merely for the purpose of combining a plurality of substrates 10 to make them freestandable, that is, merely for the purpose of temporarily fastening them. In other words, the film thickness of the GaN film 14 is preferably limited to a minimum necessary thickness for maintaining a combined state of adjacent substrates 10 even when the combined substrate 15 composed of the mutually combined substrates 10, is removed from the holding plate 12 and subjected to cleaning, etc., in step 4 described later.

The film thickness of the GaN film 14 can be suitably selected according to the abovementioned purposes, from a film thickness band having a prescribed width. For example, the film thickness of the GaN film 14 may be set to a prescribed thickness in a range of 3D or more and 100D μm or less when an outer diameter of the combined substrate 15 is set to D cm. When the film thickness of the GaN film 14 is less than 3D μm, the combining strength between adjacent substrates 10 is insufficient, and in steps 4 and 5 described later, the freestanding state of the combined substrate 15 cannot be maintained, and subsequent steps cannot be performed. Further, when the film thickness of the GaN film 14 exceeds 100D μm, waste of various gases used for film-formation, or reduction of productivity of the GaN substrate 30 in total, is caused in some cases. When the outer diameter of the substrate 10 is 2 inches and the outer diameter of the combined substrate 15 is 6 to 8 inches, the film thickness of the GaN film 14 can be set in a thickness, for example, in a range of 50 μm or more and 2 mm or less.

### (Step 4: Peeling of the Holding Plate and Cleaning)

When the growth of the GaN film 14 is completed and adjacent substrates 10 are in the state of being combined with each other, supply of HCl gas and H₂ gas into the film-forming chamber 201, and heating by the heater 207, are respectively stopped in a state of supplying NH₃ gas and N₂ gas into the film-forming chamber 201 and exhausting the inside of the film-forming chamber 201. Then, after the temperature in the film-forming chamber 201 is 500° C. or less, supply of NH₃ gas is stopped, and thereafter the atmosphere in the film-forming chamber 201 is substituted with N₂ gas, and is restored to an atmospheric pressure, and the temperature in the film-forming chamber 201 is lowered to a temperature capable of unloading the assembled substrate 13 therefrom. After such a temperature is lowered, the assembled substrate 13 is unloaded from the film-forming chamber 201. Then, the holding plate 12 is removed from the group of a plurality of substrates 10 which are in the combined state. Thereafter, the adhesive agent 11, etc., adhered to the back surface of the substrates 10, is removed using a cleaning agent such as an aqueous hydrogen fluoride (HF).

Through the above steps, the combined substrate 15 becomes freestandable, which is formed by combining adjacent substrates 10 by the GaN film 14. As described above, by setting the film thickness of the GaN film 14 as the abovementioned film thickness, the combined state of adjacent substrates 10, namely, a freestanding state of the combined substrate 15 can be maintained when the holding plate 12 is peeled-off and cleaning is performed. Also, as described above, the combined substrate 15 obtained here can be considered as one of the modes of the substrate 20 in this embodiment.

### (Step 5: Liquid-Phase Growth Step)

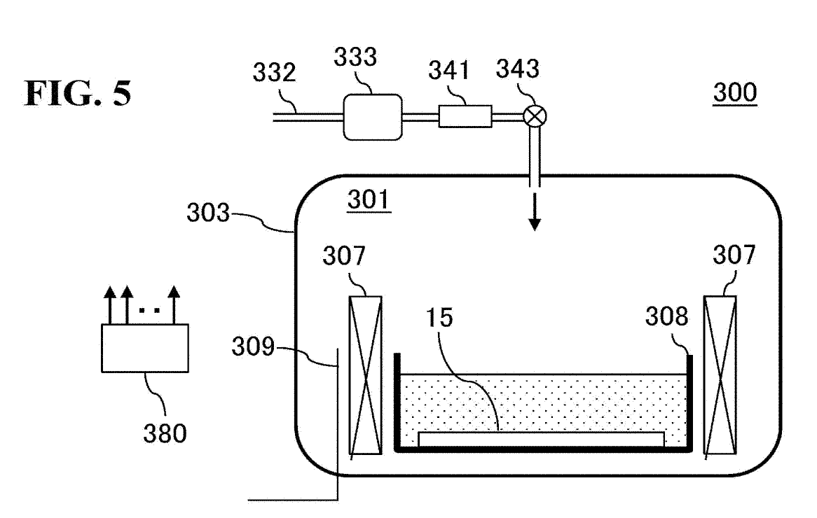

When the V-groove is formed on the surface of the combined substrate 15 in a freestanding state, a GaN crystal film 18 (also referred to as a GaN film 18) as a second crystal film (surface smoothened film) is grown on the main surface of the combined substrate 15, using a flux liquid-phase growth apparatus 300 shown in FIG. 5.

The flux liquid-phase growth apparatus 300 is made of stainless (SUS), etc., and includes a pressure-resistant container 303 having a pressurizing chamber 301 formed therein. Inside of the pressurizing chamber 301 is configured so that a pressure can be raised in a high pressure state of about 5 MPa for example. A crucible 308, a heater 307 for heating inside of the crucible 308, and a temperature sensor 309 for measuring a temperature of the inside of the pressurizing chamber 301 are provided in the pressurizing chamber 301. The crucible 308 is configured so that a Ga solution (raw material solution) can be contained therein, in which for example sodium (Na) is used as a solvent (flux), and the abovementioned combined substrate 15 can be immersed in the raw material solution, with the main surface (crystal growth surface) faced upward. A gas supply pipe 332 for supplying N₂ gas or NH₃ gas (or mixed gas of them) into the pressurizing chamber 301, is connected to the pressure-resistant container 303. A pressure control device 333, a flow rate controller 341, and a valve 343 are provided on the gas supply pipe 332 sequentially from an upstream side. Each member provided in the flux liquid-phase growth apparatus 300, is connected to a controller 380 configured as a computer, and is configured to control processing procedures and processing conditions described later, based on a program executed by the controller 380.

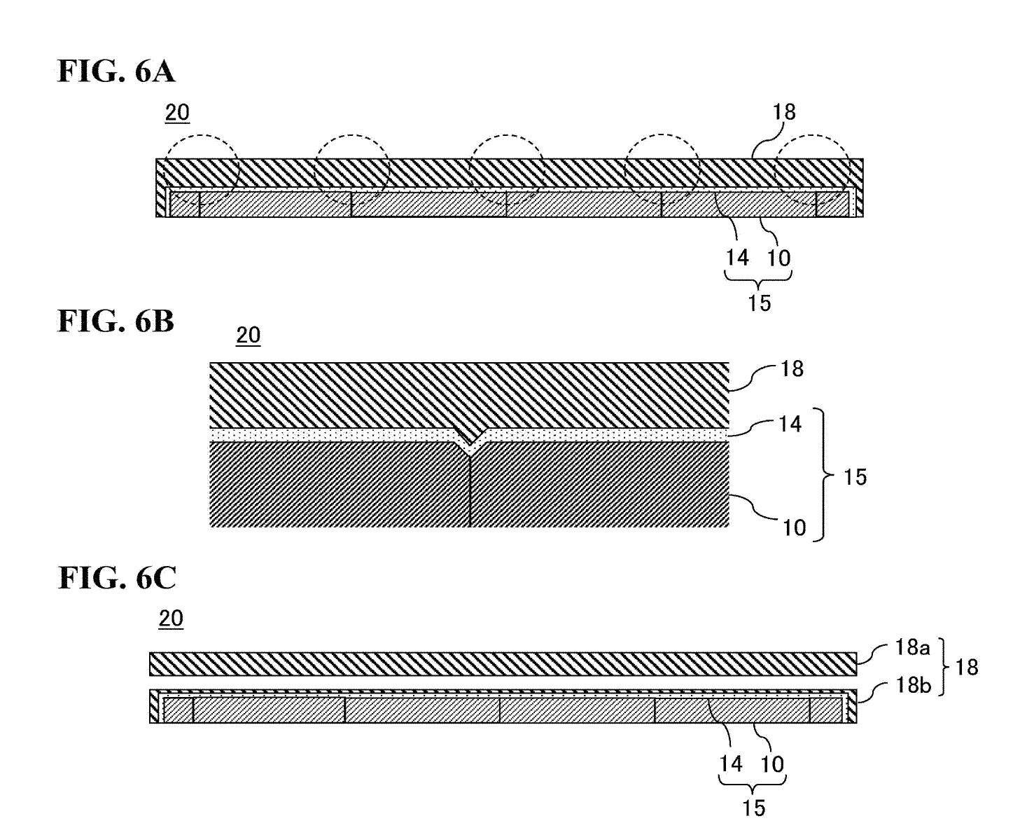

Step 5 can be performed using the abovementioned flux liquid-phase growth apparatus 300, for example based on the following processing procedures. First, the combined substrate 15 and raw materials (Na metal and Ga metal) are put in the crucible 308, and the pressure-resistant container 303 is sealed. Then, the raw material solution (Ga solution using Na as a medium) is produced in the crucible 308 by starting heating by the heater 307, thus creating a state in which the combined substrate 15 is immersed in the raw material solution. In this state, N₂ gas (or mixed gas of NH₃ gas and N₂ gas) is supplied into the pressurizing chamber 301 and nitrogen (N) is dissolved in the raw material solution, and such a state is maintained for a prescribed time. In this manner, GaN crystal is epitaxially grown on the main surface of the combined substrate 15, namely, on the surface of the GaN film 14, to thereby form a GaN film 18. FIG. 6A shows a cross-sectional configuration view of the substrate 20, which is formed by the growth of the GaN film 18 on the main surface of the combined substrate 15. After the growth of the GaN film 18 is completed, inside of the pressure-resistant container 303 is restored to the atmospheric pressure, and the substrate 20 is taken out from the inside of the crucible 308.

Step 5 is performed based on the following processing conditions for example:

Film-forming temperature (temperature of the raw material solution): 600 to 1200° C., and preferably 800 to 900° C.

Film-forming pressure (pressure in the pressurizing chamber): 0.1 Pa to 10 MPa, and preferably 1 MPa to 6 MPa

Ga concentration in the raw material solution [Ga/(Na+Ga)]: 5 to 70%, and preferably 10 to 50%

By growing the GaN film 18 under the abovementioned conditions, GaN crystal is grown in the V-groove that is formed at the combined part of the substrates 10, and the GaN film 18 can be embedded in the V-groove. As a result, the V-groove can disappear, and the substrate 20 having a smoothened main surface can be prepared. FIG. 6B shows a state in which the GaN film 18 is embedded in the V-groove.

It should be noted that the disappearance of the V-groove by embedding GaN crystal therein is difficult when the vapor-phase growth method such as HVPE method, is used as described above. By using the liquid-phase growth method such as a Na flux method, the V-groove can be made to disappear. In this case, as shown in this embodiment, the V-groove can surely disappear by setting the following state: all lateral surfaces of the substrate 10 in contact with the lateral surfaces of other substrates 10 are M-planes or a-planes, and are the planes in the same orientation each other.

The following method is also conceivable: the liquid-phase growth of step 5 is continued after making the V-groove disappear, so that the GaN film 18 is grown in a thickness of about 1 to 20 mm for example, and thereafter such a thickly grown GaN film 18 is sliced, to thereby obtain a plurality of GaN substrates. However, in the liquid-phase growth method such as Na flux method, a film-forming rate (crystal growth rate) is smaller than that of the vapor-phase growth method such as HVPE method, and a considerable amount of time is required to complete its manufacture, for obtaining a final GaN substrate by continuing the liquid-phase growth. Therefore, here, the liquid-phase growth is performed merely for the purpose of causing disappearance of the V-groove formed on the main surface of the GaN film 14, that is, merely for the purpose of smoothing the main surface of the substrate 20, and the processing is preferably moved to the subsequent step 6 (vapor-phase growth step) as early as possible. In other words, a film thickness of the GaN film 18 is preferably limited to a minimum necessary thickness for smoothing the main surface of the substrate 20 by embedding the GaN film 18 in the V-groove.

The film thickness of the GaN film 18 can be suitably selected according to the abovementioned purposes, from a film thickness band having a prescribed width. In order to surely make the V-groove disappear, the thickness of the GaN film 18 can be set to a prescribed thickness, for example, in a range of 0.8 times or more and 1.2 times or less of the size of the V-groove (larger one of a depth or an opening width). When the film thickness of the GaN film 18 is too small, disappearance of the V-groove becomes sometimes insufficient. When the film thickness of the GaN film 18 is too large, a surface morphology state of the GaN film 18 is deteriorated, and remarkable Na inclusion phenomenon occurs on the surface of the GaN film 18 in which Na used as a flux is incorporated into the surface of the GaN film 18. Further, when the film thickness of the GaN film 18 is too large, waste of the raw material solution or various gases used for film-formation, or reduction of productivity of the GaN substrate in total as a final product, is caused in some cases. When the depth or the opening width of the V-groove is about 200 μm, the film thickness of the GaN film 18 can be set to the thickness, for example, in a range of 160 μm or more and 240 μm or less.

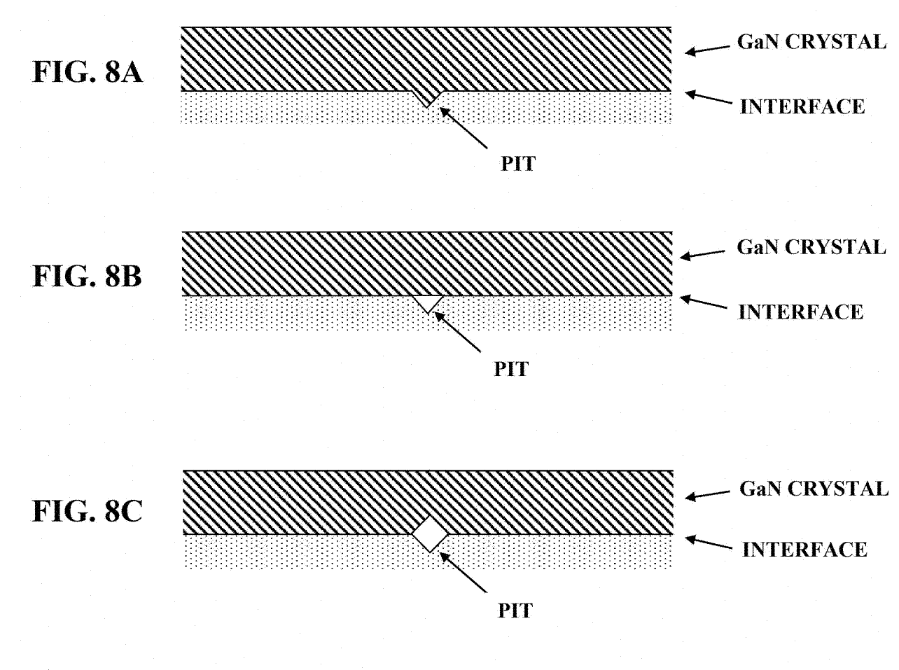

In this embodiment, the Na flux method is used as the liquid-phase growth method. However, in this case, Na used as a flux is sometimes incorporated into a pit or the like that exists on the interface between the GaN film 14 and the GaN film 18. This is because as shown in FIG. 8A, when GaN crystal grows so as to embed inside of the pit, Na is hardly incorporated into the pit. However, when the pit is sealed due to a rapid lateral growth of GaN crystal above the pit as shown in FIG. 8B, or when the pit is sealed due to a gradual lateral growth of GaN crystal above the pit as shown in FIG. 8C, Na is easily incorporated into the pit. Particularly, when the crystal grows as shown in FIG. 8C, an amount of Na incorporated into the pit is likely to be increased.

Burst of Na incorporated into the interface occurs when the substrate 20 is heated in the step 6 (vapor-phase growth step) performed thereafter, which may damage the GaN film 18 in some cases. Therefore, in this embodiment, as shown in FIG. 6C, a layer 18a having a low Na-containing concentration in the GaN film 18 is cut out, and this layer 18a may be used as the substrate 20. Further in this case, front and back surfaces of the cutout layer 18a may be polished. According to the studies of the inventors, it is known that an area into which Na is incorporated at a high concentration due to a growth by the Na flux method, is limited only to the periphery of the interface. For example, when the size (larger one of a depth or an opening width) of the pit that exists on the interface is about 3 μm, it is known that an area into which Na is incorporated at a high concentration, is limited to an area within a range of 2.5 μm from the interface. Therefore, when the layer 18a is cut out from the GaN film 18 and a cutout surface thereof is polished or the like, almost no Na is included in the layer 18a (substrate 20).

When the abovementioned cutout processing is performed, the film thickness of the GaN film 18 is preferably set to a thickness such as enabling the layer 18a to be cut out as one substrate, that is, set to a thickness that allows the cutout layer 18a to be maintained in a freestanding state. By setting the film thickness of the GaN film 18 to 0.5 mm or more for example, and preferably 1 mm or more, the layer 18a can be cut out and set in the freestanding state. In this case, the substrate 20 does not include the substrates 10, but under an influence of the combined part of the substrates 10, the substrate 20 (the layer 18a) has a high defect area in which defect density and internal distortion are relatively larger, that is, has an area in which strength and quality are relatively deteriorated. The high defect area has a larger defect density (internal distortion) than an average defect density (or internal distortion) in the GaN film 18. The existence of such a high defect area can be observed visually in some cases due to the formation of grooves or steps on the surface, or cannot be observed visually in some cases. Even when it cannot be observed visually, the existence of the high defect area can be recognized by using a publicly-known analysis technique such as X-ray diffraction.

Here, explanation is given for a case in which the layer 18a having a low Na-containing concentration is cut out and used as the substrate 20, but this embodiment is not limited to such a mode. This is because in the Na flux method, crystal growth in a lateral direction (in a direction orthogonal to the c-axis) of GaN crystal can be promoted, by appropriately selecting the processing conditions, etc. Accordingly, the amount of Na incorporated into the interface can be suppressed.

For example, the crystal growth in the direction orthogonal to the c-axis can be promoted by setting a molar ratio (Ga/Na) of Ga with respect to Na to be small in the raw material solution contained in the crucible 308. Thus, the crystal growth type shown in FIG. 8C is suppressed, and the ratio of the crystal growth type shown in FIG. 8A or FIG. 8B is increased, and the amount of Na incorporated into the interface can be considerably reduced. In this case, the substrate shown in FIG. 6A can be used as the substrate 20 without cutting out the layer 18a from the GaN film 18, that is, while keeping an integral state of the GaN film 18 and the substrates 10. When the size of the V-groove is about 200 μm, the film thickness of the GaN film 18 can be set to the thickness, for example, in a range of 160 μm or more and 240 μm or less as described above.

Promotion of the crystal growth in the direction orthogonal to the c-axis can also be performed not only by setting the abovementioned molar ratio, but also, for example by setting a film-forming pressure. For example, by setting a pressure of the inside of the pressurizing chamber 301 to a high pressure and setting a temperature therein to a low temperature, the amount of N incorporated into the raw material solution is increased (the degree of supersaturation is increased), and the crystal growth of GaN crystal in the direction orthogonal to the c-axis can be promoted. Further, by setting the pressure of the inside of the pressurizing chamber 301 to a low pressure and setting the temperature therein to a high temperature, the amount of N incorporated into the raw material solution is decreased (the degree of supersaturation is decreased), and the crystal growth of GaN crystal in the c-axis direction can be promoted. For example, by setting the film-forming pressure to 3 MPa to 5 MPa, and preferably setting it to about 4 MPa, the crystal growth in the direction orthogonal to the c-axis can be promoted, and the effect similar to above can be obtained.

Further, promotion of the crystal growth in the direction orthogonal to the c-axis can also be performed by setting a stirring direction of the raw material solution for example. By setting the stirring direction of the raw material solution to a lateral direction, the crystal growth in the direction orthogonal to the c-axis can be promoted, and the effect similar to above can be obtained.

These methods can be used arbitrarily in combination. The processing conditions such as the film-forming pressure and the temperature, may be changed according to a progress of the film-formation processing. For example, the pressure may be increased or the temperature may be lowered for promoting the crystal growth in the direction orthogonal to the c-axis in an initial stage of the growth of the GaN film 18, and the pressure may be reduced or the temperature may be raised for promoting the crystal growth in the c-axis in a middle stage of the growth of the GaN film 18 or subsequent stages after the middle stage.

### (Step 6: Vapor-Phase Growth and Slicing)

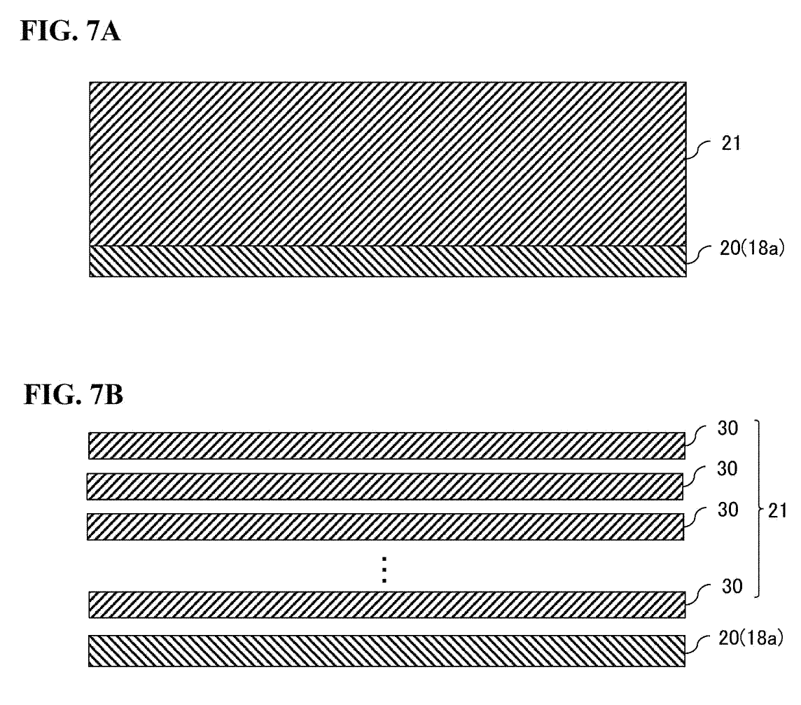

When the preparation of the substrate 20 is completed, a GaN film 21 as a third crystal film (full growth film) is grown on the smoothened main surface of the substrate 20, namely on the ground surface belonging to the substrate 20, by the processing procedure similar to that of step 3, using the HVPE apparatus 200 shown in FIG. 3. FIG. 7A shows a state in which the GaN film 21 is formed thick on the smoothened main surface of the substrate 20, that is, on the main surface of the GaN film 18 by the vapor-phase growth method.

Processing conditions in step 6 can be the same as the abovementioned processing conditions in step 3, but it is preferable to make the processing conditions different between them. This is because the film-formation processing in step 3 is performed for the main purpose of combining the substrates 10. Therefore, in step 3, it is preferable to grow crystal under a condition that emphasizes a growth in a direction along the main surface (c-plane) (direction orthogonal to the c-axis, direction along the surface), rather than the growth toward the main surface direction (c-axis direction). In contrast, the film-formation processing in step 6 is performed for the main purpose of growing the GaN film 21 thick on the substrate 20 at a high speed. Therefore, in step 6, it is preferable to grow crystal under a condition that emphasizes the growth toward the main surface direction rather than the growth toward the direction along the surface.

As a method for achieving the abovementioned purposes, for example, there is a method of making an atmosphere in the film-forming chamber 201 different between step 3 and step 6. For example, the ratio (N₂/H₂) of a partial pressure of N₂ gas to a partial pressure of H₂ gas in the film-forming chamber 201 in step 6, is set to be smaller than the ratio (N₂/H₂) of a partial pressure of N₂ gas to a partial pressure of H₂ gas in the film-forming chamber 201 in step 3. As a result, the crystal growth toward the direction along the surface becomes relatively active in step 3, and the crystal growth toward the main surface direction becomes relatively active in step 6.

As another method for achieving the abovementioned purposes, for example, there is a method of making a film-forming temperature different between step 3 and step 6. For example, the film-forming temperature in step 6 is set to be lower than the film-forming temperature in step 3. As a result, the crystal growth toward the direction along the surface becomes relatively active in step 3, and the crystal growth toward the main surface direction becomes relatively active in step 6.

As still another method for achieving the abovementioned purposes, for example, there is a method of making a ratio (NH₃/GaCl) of the supply flow rate of NH₃ gas to the supply flow rate of GaCl gas different between step 3 and step 6. For example, NH₃/GaCl ratio in step 6 is set to be larger than NH₃/GaCl ratio in step 3. As a result, the crystal growth toward the direction orthogonal to the c-axis becomes relatively active in step 3, and the crystal growth toward the c-axis direction becomes relatively active in step 6.

Step 6 is performed based on the following processing conditions for example:

Film-forming temperature (temperature of the substrate for crystal growth): 980 to 1100° C.

Film-forming pressure (pressure in the film-forming chamber): 90 to 105 kPa, and preferably 90 to 95 kPa

Partial pressure of GaCl gas: 1.5 to 15 kPa

Partial pressure of NH₃ gas/Partial pressure of GaCl gas: 4 to 20

Flow rate of N₂ gas/Flow rate of H₂ gas: 0 to 1

After growth of the GaN film 21, the film-formation processing is stopped by the processing procedure similar to the processing procedure in the end of step 3, and the substrate 20 with the GaN film 21 formed thereon, is unloaded from the film-forming chamber 201. Thereafter, the GaN film 21 is sliced, so that one or more GaN substrates 30 can be obtained as shown in FIG. 7B. An entire laminated structure of the substrate 20 and the GaN film 21 can also be considered as a GaN substrate. When the substrate 20 is cut out from the GaN film 21, step 6 can be performed again using the cutout substrate 20, that is, the cutout substrate 20 can be reused.

(2) Effect Obtained by this Embodiment

According to this embodiment, one or a plurality of effects shown below can be obtained.

(a) By matching a plurality of relatively small diameter substrates 10, the outer diameter and the shape of the substrate 20 can be arbitrarily changed. In this case, even when the diameter of the substrate 20 is increased, increase of the variation of the off-angle in its main surface can be suppressed. For example, the variation of the off-angle in the main surface of the entire substrate 20 can be equal to or less than the variation of the off-angle in the main surface of each substrate 10. In this manner, by using the large diameter substrate 20 with less variation of off-angle, high-quality GaN substrate 30 can be manufactured.
(b) By setting the difference of the lattice constant between adjacent substrates 10 within 7×10⁻⁵ Å, it is possible to improve the quality of the GaN film 14 grown at the combined part between adjacent substrates 10, and increase the combining strength between adjacent substrates 10. As a result, the finally obtained GaN substrate 30 can be a high-quality substrate. When the O concentration of adjacent substrates 10 is within the range (C₁) of 1×10¹⁷ to 5×10¹⁹ at/cm³ respectively, the difference of the lattice constant satisfies the abovementioned requirements by setting the difference of the O concentration between adjacent substrates 10 within 9.9×10¹⁸ at/cm³, and the abovementioned effect can be obtained. Also, by setting the O concentration of adjacent substrates 10 within the range (C₂) of 1×10¹⁹ at/cm³ or less respectively, the difference of the lattice constant between adjacent substrates 10 always satisfies the abovementioned requirements irrespective of the difference of the O concentration, and the abovementioned effect can be surely obtained.
(c) By setting the difference of the lattice constant between adjacent substrates 10 within 2×10⁻⁵ Å, it is possible to further improve the quality of the GaN film 14 grown at the combined part between adjacent substrates 10, and further increase the combining strength between adjacent substrates 10. As a result, the finally obtained GaN substrate 30 can be a further high-quality substrate. When the O concentration of adjacent substrates 10 is within the range (C₁) of 1×10¹⁷ to 5×10¹⁹ at/cm³ respectively, the difference of the lattice constant satisfies the abovementioned requirements by setting the difference of the O concentration between adjacent substrates 10 within 2.9×10¹⁸ at/cm³, and the abovementioned effect can be obtained. Also, by setting the O concentration of adjacent substrates 10 within the range (C₃) of 3×10¹⁸ at/cm³ or less respectively, the difference of the lattice constant between adjacent substrates 10 always satisfies the abovementioned requirements irrespective of the difference of the O concentration, and the abovementioned effect can be surely obtained.
(d) By setting the difference of the lattice constant between the substrate 10 and the GaN film 14 within 7×10⁻⁵ Å, it is possible to improve the quality of the GaN film 14. As a result, the finally obtained GaN substrate 30 can be a high-quality substrate. When the O concentration of the substrate 10 and the GaN film 14 is within the range (C₁) of 1×10¹⁷ to 5×10¹⁹ at/cm³ respectively, the difference of the lattice constant satisfies the abovementioned requirements by setting the difference of the O concentration between the substrate 10 and the GaN film 14 within 9.9×10¹⁸ at/cm³, and the abovementioned effect can be obtained. Also, by setting the O concentration of the substrate 10 and the GaN film 14 within the range (C₂) of 1×10¹⁹ at/cm³ or less respectively, the difference of the lattice constant between the substrate 10 and the GaN film 14 always satisfies the abovementioned requirements irrespective of the difference of the O concentration, and the abovementioned effect can be surely obtained.
(e) By setting the difference of the lattice constant between the substrate 10 and the GaN film 14 within 2×10⁻⁵ Å, it is possible to further improve the quality of the GaN film 14. As a result, the finally obtained GaN substrate 30 can be a further high-quality substrate. When the O concentration of the substrate 10 and the GaN film 14 is within the range (C₁) of 1×10¹⁷ to 5×10¹⁹ at/cm³ respectively, the difference of the lattice constant satisfies the abovementioned requirements by setting the difference of the O concentration between the substrate 10 and the GaN film 14 within 2.9×10¹⁸ at/cm³, and the abovementioned effect can be obtained. Also, by setting the O concentration of the substrate 10 and the GaN film 14 within the range (C₃) of 3×10¹⁸ at/cm³ or less respectively, the difference of the lattice constant between the substrate 10 and the GaN film 14 always satisfies the abovementioned requirements irrespective of the difference of the O concentration, and the abovementioned effect can be surely obtained.
(f) By combining the substrates 10 by vapor-phase growing the GaN film 14, namely, by combining the substrates 10 using the film having the same material and the same composition as those of the film to be liquid-phase grown in step 5, the GaN film 14 is hardly melted and the combination of the substrate 10 is hardly come off even when the liquid-phase growth step is performed in step 5. Even when a part of the GaN film 14 is dissolved into the raw material solution, it is possible to avoid an influence on the crystallinity of the GaN film 18 to be grown in step 5.

In contrast, for example, when step 5 (liquid-phase growth step) is performed after steps 1 and 2 are performed without performing step 3 (combination by vapor-phase growth), the adhesive agent 11 is dissolved into the raw material solution in the process of the liquid-phase growth, then the substrate 10 comes off from the holding plate 12, or the crystallinity, etc., of the GaN film 18 is deteriorated under an influence of the dissolved adhesive agent 11 in some cases.

(g) Instead of manufacturing the GaN substrate 30 only through the vapor-phase growth step of step 3 and step 6, step 5 (liquid-phase growth step) is interposed between step 3 and step 6, and therefore it is possible to surely make the V-groove disappear from the surface of the substrate 20. As a result, high-quality GaN substrate 30 can be manufactured with no necessity for passing through extra steps of stopping the vapor-phase growth of the GaN crystal film in the middle and cutting the surface of the grown GaN crystal film or the like. Further, the number of screw dislocations included in the GaN substrate 30 can be reduced by interposing step 5 between step 3 and step 6. This is because when the combined substrate 15 is immersed in the raw material solution in step 5, a part of the surface of the GaN film 14 which is the base of the crystal growth is melt-backed, and the screw dislocation included therein is not taken over into the growth layer.

In contrast, for example when step 6 (vapor-phase growth step) is performed after steps 1 to 3 are performed without performing step 5 (liquid-phase growth step), etc., the GaN film 21 formed in step 6 is exposed to a great influence of the V-groove formed on the surface of the GaN film 14, thereby deteriorating the crystallinity, etc., of the GaN substrate 30 in some cases. Further, in order to cut off the influence of the V-groove, there is a new necessity for stopping step 6 in the middle and cutting the surface of the GaN film 21 or the like, and thereafter restarting step 6. In this case, productivity is reduced in some cases.

(h) The liquid-phase growth in step 5 is performed for the main purpose of making the V-groove disappear, the V-groove being formed on the surface of the GaN film 14, and a full-scale growth of the thick film is performed in the vapor-phase growth step of step 6. Productivity of the GaN substrate 30 can be improved because the film-forming rate is larger in the vapor-phase growth than that of the liquid-phase growth. In contrast, when the thick film is grown by continuing step 5 for a long time after steps 1 to 4 are performed, reduction of the productivity is caused in some cases as described above.
(i) By forming all lateral surfaces of the substrates 10 in contact with the lateral surfaces of other substrates 10, as M-plane or a-plane and as the planes having the same orientation each other, the V-groove formed on the surface of the GaN film 14 can further surely disappear when step 5 (liquid-phase growth step) is performed. For example, by combining adjacent substrates 10 by M-planes or a-planes, the V-groove can further surely disappear than a case of combining them by the planes excluding M-planes or a-planes.

### Other Embodiment

As described above, embodiments of the present invention have been described specifically. However, the present invention is not limited to the abovementioned embodiments, and can be variously modified in a range not departing from the gist of the invention.

In the abovementioned embodiment, explanation is given for a case in which the vapor-phase growth step of step 3 and the liquid-phase growth step of step 5 are performed. However, the present invention is not limited to such a mode, and these steps may be omitted. Further, in the abovementioned embodiment, explanation is given for a case in which the layer 18a is cut out and the front and back surfaces of the layer 18a are polished in the step 5. However, the present invention is not limited to such a mode, and these processing may be omitted.

For example, in the abovementioned embodiment, explanation is given for a case of using the Hydride Vapor-Phase Epitaxy (HVPE) method as the vapor-phase growth method in steps 3 and 6. However, the present invention is not limited to such a mode. For example, in either one or both of steps 3 and 6, the vapor-phase growth method other than HVPE method, such as metal organic chemical vapor deposition (MOCVD) method or oxygen vapor-phase epitaxy (OVPE) method may be used. In this case as well, the same effect as the effect of the abovementioned embodiment can be obtained.

Further for example, in the abovementioned embodiment, explanation is given for a case of performing the liquid-phase growth in step 5 by the flux method in which Na is used as flux. However, the present invention is not limited to such a mode. For example, alkali metal other than Na, such as lithium (Li) may be used as the flux. Further, the liquid-phase growth may be performed using a method such as a melt growth method or an ammonothermal method performed under high pressure and high temperature, other than the flux method. In these cases as well, the same effect as the effect of the abovementioned embodiment can be obtained.

Further for example, in the abovementioned embodiment, explanation is given for a case of adhering the holding plate 12 and the substrates 10 using the adhesive agent 11. However, the present invention is not limited to such a mode. For example, a substrate made of GaN polycrystal (GaN polycrystalline substrate) may be used as the holding plate 12, and the holding plate 12 and the substrates 10 may be directly adhered without using the adhesive agent 11. For example, by plasma-treating the surface of the holding plate 12 made of GaN polycrystal, its main surface is terminated with OH group and thereafter the substrates 10 are directly placed on the main surface of the holding plate 12, so that they can be adhered integrally. Then, by applying annealing to a laminate formed by adhering the holding plate 12 and the substrates 10, moisture, etc., remained between the holding plate 12 and the substrates 10 can be removed, and such a laminate can be suitably used as the abovementioned assembled substrate 13 or as the combined substrate 15.

The present invention is not limited to GaN, and can be suitably applied to a case when manufacturing a substrate made of nitride crystals such as aluminum nitride (AlN), aluminum gallium nitride (AlGaN), indium nitride (InN), indium gallium nitride (InGaN), and aluminum indium gallium nitride (AlInGaN), that is, made of nitride crystals represented by a composition formula of AlₓIn_{y}Ga_{1-x-y}N (0≦x+y≦1).

### Examples

Various test results that support the effect of the present invention will be described hereafter.

As sample 1, seed crystal substrates made of GaN single crystals whose planar shape was a regular hexagonal shape were prepared, and a GaN crystal film was grown on the main surface of the seed crystal substrates using HVPE method. As the seed crystal substrate, a substrate having the O concentration of 1×10¹⁹ at/cm³ was prepared. The main surface (crystal growth surface) of the seed crystal substrate was set as c-plane, and all lateral surfaces were set as a-planes. The GaN crystal film was grown under a condition such that the O concentration was 1×10¹⁷ at/cm³. Based on the theoretical formula introduced in the abovementioned embodiment, the lattice constant on the a-plane of the seed crystal substrate is 3.18805 Å, and the lattice constant on the a-plane of the GaN crystal film is 3.18796 Å. Namely, the difference of the lattice constant between the seed crystal substrate and the crystal film is 9×10⁻⁵ Å.

As sample 2, a plurality of seed crystal substrates made of GaN single crystals whose planar shape was a regular hexagonal shape were prepared by the method described in the abovementioned embodiment, and they were arranged in a planar appearance (tessellation), and thereafter the GaN crystal film was grown on the main surface of them, to thereby manufacture the substrate for crystal growth. As the seed crystal substrates, the substrates having the O concentration of 5×10¹⁸ at/cm³ respectively were prepared. The main surfaces (crystal growth surfaces) of the seed crystal substrates were set as c-plane, and all lateral surfaces were set as a-planes. The GaN crystal film was grown under a condition such that the O concentration was 1×10¹⁷ at/cm³. Based on the abovementioned theoretical formula, the lattice constant on the a-plane of the seed crystal substrate is 3.18801 Å, and the lattice constant on the a-plane of the GaN crystal film is 3.18796 Å. Namely, the difference of the lattice constant between the seed crystal substrate and the crystal film is 5×10⁻⁵ Å.

As sample 3, a plurality of seed crystal substrates made of GaN single crystals whose planar shape was a regular hexagonal shape were prepared by the method described in the abovementioned embodiment, and they were arranged in a planar appearance (tessellation), and thereafter the GaN crystal film was grown on the main surface of them, to thereby manufacture the substrate for crystal growth. As the seed crystal substrates, the substrates having the O concentration of 1×10¹⁸ at/cm³ respectively were prepared. The main surfaces (crystal growth surfaces) of the seed crystal substrates were set as c-plane, and all lateral surfaces were set as a-planes. The GaN crystal film was grown under a condition such that the O concentration was 1×10¹⁷ at/cm³. Based on the abovementioned theoretical formula, the lattice constant on the a-plane of the seed crystal substrate is 3.18797 Å, and the lattice constant on the a-plane of the GaN crystal film is 3.18796 Å. Namely, the difference of the lattice constant between the seed crystal substrate and the crystal film is 1×10⁻⁵ Å.

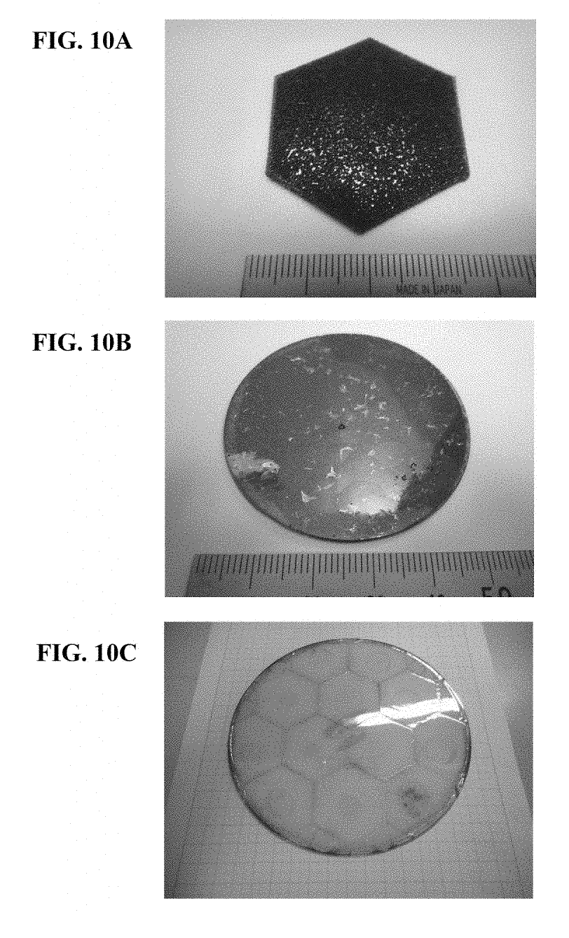

FIGS. 10A to 10C show the surface photographs of the prepared samples 1 to 3, respectively.

As shown in FIG. 10A, in sample 1, it is found that the surface of GaN crystal grown on the seed crystal substrate is not planarized and no continuous film is formed. It is considered that this is because, as described above, the difference of the lattice constant between the seed crystal substrate and the crystal film is larger than the requirements imposed in the abovementioned embodiment. Inventors of the present invention already confirm that it becomes difficult to epitaxially grow the GaN crystal film when the difference of the lattice constant between the seed crystal substrate and the crystal film exceeds 7×10⁻⁵ Å. The inventors also confirm that even when a plurality of seed crystal substrates are prepared, and they are arranged in a planar appearance (tessellation), it is difficult to combine them by the GaN crystal film when the difference of the lattice constant between adjacent seed crystal substrates exceeds 7×10⁻⁵ Å.

As shown in FIG. 10B, in sample 2, it is found that a high-quality GaN substrate grows on the seed crystal substrates, with GaN crystal epitaxially grown thereon, having a planarized surface (mirror surface) with almost no cracks or the like. It can be considered that this is because the difference of the lattice constant between the seed crystal substrate and the crystal film is smaller than that of the sample 1 and satisfies the requirements imposed in the abovementioned embodiment. The inventors already confirm that by suppressing the difference of the lattice constant between the seed crystal substrate and the crystal film to 7×10⁻⁵ Å or less, it becomes possible to epitaxially grow the GaN crystal film and make it a sufficiently high-quality film. The inventors also confirm that by suppressing the difference of the lattice constant between adjacent seed crystal substrates to 7×10⁻⁵ Å or less, it becomes possible to combine the adjacent seed crystal substrates by the GaN crystal film with sufficient strength, and the combined substrate can be a freestanding substrate as the substrate for crystal growth.

As shown in FIG. 10C, in sample 3, it is found that a further high-quality GaN substrate grows on the seed crystal substrate, with GaN crystal epitaxially grown thereon, having a further planarized surface with no cracks or the like. It can be considered that this is because the difference of the lattice constant between the seed crystal substrate and the crystal film is smaller than that of the sample 2. The inventors already confirm that by suppressing the difference of the lattice constant between the seed crystal substrate and the crystal film to 2×10⁻⁵ Å or less, it becomes possible to make the GaN crystal film as such an extremely high-quality epitaxial film. The inventors also confirm that by setting the difference of the lattice constant between adjacent seed crystal substrates to 2×10⁻⁵ Å or less, it is possible not only to set the substrate for crystal growth in a freestanding state but also to form the substrate with little warpage

### <Preferred Aspects of the Present Invention>

Preferred aspects of the present invention will be supplementarily described hereafter.

### (Supplementary Description 1)

According to an aspect of the present invention, there is provided a method for manufacturing a nitride crystal substrate, including:

a first step of preparing a substrate for crystal growth having a plurality of seed crystal substrates made of nitride crystals, arranged in a planar appearance, so that their main surfaces are parallel to each other and their lateral surfaces are in contact with each other, and a difference of a lattice constant between adjacent seed crystal substrates arbitrarily selected from a plurality of the seed crystal substrates is within 7×10⁻⁵ Å; and

a second step of growing a crystal film on a ground surface belonging to the substrate for crystal growth.

### (Supplementary Description 2)

Preferably, there is provided the method according to supplementary description 1, wherein in the first step, a substrate in which a difference of a lattice constant between the adjacent seed crystal substrates is within 2×10⁻⁵ Å, is prepared as the substrate for crystal growth.

### (Supplementary Description 3)

According to other aspect of the present invention, there is provided a method for manufacturing a nitride crystal substrate, including:

a first step of preparing a substrate for crystal growth having a plurality of seed crystal substrates made of nitride crystals, arranged in a planar appearance, so that their main surfaces are parallel to each other and their lateral surfaces are in contact with each other; and

a second step of growing a crystal film on a ground surface belonging to the substrate for crystal growth, wherein a difference of a lattice constant with respect to a seed crystal substrate arbitrarily selected from a plurality of the seed crystal substrates is within 7×10⁻⁵ Å.

### (Supplementary Description 4)

Preferably, there is provided the method according to supplementary description 3, wherein in the second step, a film in which a difference of a lattice constant with respect to the seed crystal substrate arbitrarily selected from a plurality of the seed crystal substrates is within 2×10⁻⁵ Å, is grown as the crystal film.

### (Supplementary Description 5)

According to further other aspect of the present invention, there is provided a method for manufacturing a nitride crystal substrate, including:

a first step of preparing a substrate for crystal growth having a plurality of seed crystal substrates made of nitride crystals, arranged in a planar appearance, so that their main surfaces are parallel to each other and their lateral surfaces are in contact with each other, and a difference of an oxygen concentration between adjacent seed crystal substrates arbitrarily selected from a plurality of the seed crystal substrates is within 9.9×10¹⁸ at/cm³; and

a second step of growing a crystal film on a ground surface belonging to the substrate for crystal growth.

### (Supplementary Description 6)

Preferably, there is provided the method according to the supplementary description 5, wherein in the first step, a substrate in which a difference of an oxygen concentration between the adjacent seed crystal substrates is within 2.9×10¹⁸ at/cm³, is prepared as the substrate for crystal growth.

### (Supplementary Description 7)

According to further other aspect of the present invention, there is provided a method for manufacturing a nitride crystal substrate, including:

a first step of preparing a substrate for crystal growth having a plurality of seed crystal substrates made of nitride crystals, arranged in a planar appearance, so that their main surfaces are parallel to each other and their lateral surfaces are in contact with each other; and

a second step of growing a crystal film on a ground surface belonging to the substrate for crystal growth, wherein a difference of an oxygen concentration with respect to a seed crystal substrate arbitrarily selected from a plurality of the seed crystal substrates is within 9.9×10¹⁸ at/cm³.

### (Supplementary Description 8)

Preferably, there is provided the method according to supplementary description 7, wherein in the second step, a film in which a difference of an oxygen concentration with respect to the seed crystal substrate arbitrarily selected from a plurality of the seed crystal substrates is within 2.9×10¹⁸ at/cm³, is grown as the crystal film.

### (Supplementary Description 9)

Further preferably, there is provided the method according to any one of the supplementary descriptions 1 to 8, wherein in the first step, a substrate in which an oxygen concentration of a plurality of the seed crystal substrates is respectively 1×10¹⁹ at/cm³ or less, is prepared as the substrate for crystal growth.

### (Supplementary Description 10)

Further preferably, there is provided the method according to any one of the supplementary descriptions 1 to 9, wherein in the first step, a substrate in which an oxygen concentration of a plurality of the seed crystal substrates is respectively 3×10¹⁸ at/cm³ or less, is prepared as the substrate for crystal growth.

### (Supplementary Description 11)

Further preferably, there is provided the method according to the supplementary description 9, wherein in the second step, an oxygen concentration of the crystal film is set to 1×10¹⁹ at/cm³ or less.

### (Supplementary Description 12)

Further preferably, there is provided the method according to the supplementary description 10, wherein in the second step, an oxygen concentration of the crystal film is set to 3×10¹⁸ at/cm³ or less.

### (Supplementary Description 13)

Further preferably, there is provided the method according to any one of the supplementary descriptions 1 to 12, wherein in the first step, a substrate in which all of a plurality of the seed crystal substrates are made of GaN crystals, and all main surfaces of them are composed of c-planes, and all lateral surfaces in contact with other seed crystal substrates are composed of a-planes only or are composed of M-planes only, is prepared as the substrate for crystal growth.

### (Supplementary Description 14)

Further preferably, there is provided the method according to any one of the supplementary descriptions 1 to 13, wherein in the first step, a substrate in which a seed crystal substrate arbitrarily selected from a plurality of the seed crystal substrates is in contact with at least two or more other seed crystal substrates, is prepared as the substrate for crystal growth.

### (Supplementary Description 15)

Further preferably, there is provided the method according to any one of the supplementary descriptions 1 to 14, wherein in the first step, a substrate in which two or more contact surfaces of a seed crystal substrate arbitrarily selected from a plurality of the seed crystal substrates are not orthogonal to each other, is prepared as the substrate for crystal growth.

### (Supplementary Description 16)

Further preferably, there is provided the method according to any one of the supplementary descriptions 1 to 15, further including the steps of:

further growing a nitride crystal on the crystal film; and

cutting out a nitride crystal substrate from a growth layer of the nitride crystal.

### (Supplementary Description 17)

Further preferably, there is provided the method according to any one of the supplementary descriptions 1 to 15, further including the steps of:

further growing a nitride crystal on the crystal film by a liquid-phase growth method;

further growing a nitride crystal on the nitride crystal grown by the liquid-phase growth method, by a vapor-phase growth method; and

cutting out a nitride crystal substrate from the nitride crystal layer grown by the vapor-phase growth method.

### (Supplementary Description 18)

Further preferably, there is provided the method according to any one of the supplementary descriptions 1 to 15, further including the steps of:

further growing a nitride crystal on the crystal film by a liquid-phase growth method;

preparing a freestanding nitride crystal substrate by polishing front and back surfaces of the nitride crystal grown by the liquid-phase growth method;

further thickly growing a nitride crystal on the freestanding nitride crystal substrate by a vapor-phase growth method; and

cutting out a nitride crystal substrate from the nitride crystal layer grown by the vapor-phase growth method.

### (Supplementary Description 19)

According to further other aspect of the present invention, there is provided a substrate for crystal growth having a ground surface on which a nitride crystal is grown, including:

a plurality of seed crystal substrates made of nitride crystals, arranged in a planar appearance, so that their main surfaces are parallel to each other and their lateral surfaces are in contact with each other,

wherein a difference of a lattice constant between adjacent seed crystal substrates arbitrarily selected from a plurality of the seed crystal substrates is within 7×10⁻⁵ Å.

### (Supplementary Description 20)

According to further other aspect of the present invention, there is provided a substrate for crystal growth having a ground surface on which a nitride crystal is grown, including:

a plurality of seed crystal substrates made of nitride crystals, arranged in a planar appearance, so that their main surfaces are parallel to each other and their lateral surfaces are in contact with each other; and

a crystal film formed on a surface of a plurality of the seed crystal substrates arranged in a planar appearance, for combining the adjacent seed crystal substrates each other,

wherein a difference between a lattice constant of a seed crystal substrate arbitrarily selected from a plurality of the seed crystal substrates and a lattice constant of the crystal film is within 7×10⁻⁵ Å.

1. A method for manufacturing a nitride crystal substrate, comprising:
a first step of preparing a substrate for crystal growth having a plurality of seed crystal substrates made of nitride crystals, arranged in a planar appearance, so that their main surfaces are parallel to each other and their lateral surfaces are in contact with each other, and a difference of a lattice constant between adjacent seed crystal substrates arbitrarily selected from a plurality of the seed crystal substrates is within 7×10⁻⁵ Å; and
a second step of growing a crystal film on a ground surface belonging to the substrate for crystal growth.

2. The method for manufacturing a nitride crystal substrate according to claim 1, wherein in the first step, a substrate in which a difference of a lattice constant between the adjacent seed crystal substrates is within 2×10⁻⁵ Å, is prepared as the substrate for crystal growth.

3. A method for manufacturing a nitride crystal substrate, comprising:
a first step of preparing a substrate for crystal growth having a plurality of seed crystal substrates made of nitride crystals, arranged in a planar appearance, so that their main surfaces are parallel to each other and their lateral surfaces are in contact with each other; and
a second step of growing a crystal film on a ground surface belonging to the substrate for crystal growth, wherein a difference of a lattice constant with respect to a seed crystal substrate arbitrarily selected from a plurality of the seed crystal substrates is within 7×10⁻⁵ Å.

4. The method for manufacturing a nitride crystal substrate according to claim 3, wherein in the second step, a film in which a difference of a lattice constant with respect to the seed crystal substrate arbitrarily selected from a plurality of the seed crystal substrates is within 2×10⁻⁵ Å, is grown as the crystal film.

5. A method for manufacturing a nitride crystal substrate, comprising:
a first step of preparing a substrate for crystal growth having a plurality of seed crystal substrates made of nitride crystals, arranged in a planar appearance, so that their main surfaces are parallel to each other and their lateral surfaces are in contact with each other, and a difference of an oxygen concentration between adjacent seed crystal substrates arbitrarily selected from a plurality of the seed crystal substrates is within 9.9×10¹⁸ at/cm³; and
a second step of growing a crystal film on a ground surface belonging to the substrate for crystal growth.

6. The method for manufacturing a nitride crystal substrate according to claim 5, wherein in the first step, a substrate in which a difference of an oxygen concentration between the adjacent seed crystal substrates is within 2.9×10¹⁸ at/cm³, is prepared as the substrate for crystal growth.

7. A method for manufacturing a nitride crystal substrate, comprising:
a first step of preparing a substrate for crystal growth having a plurality of seed crystal substrates made of nitride crystals, arranged in a planar appearance, so that their main surfaces are parallel to each other and their lateral surfaces are in contact with each other; and
a second step of growing a crystal film on a ground surface belonging to the substrate for crystal growth, wherein a difference of an oxygen concentration with respect to a seed crystal substrate arbitrarily selected from a plurality of the seed crystal substrates is within 9.9×10¹⁸ at/cm³.

8. The method for manufacturing a nitride crystal substrate according to claim 7, wherein in the second step, a film in which a difference of an oxygen concentration with respect to the seed crystal substrate arbitrarily selected from a plurality of the seed crystal substrates is within 2.9×10¹⁸ at/cm³, is grown as the crystal film.

9. The method for manufacturing a nitride crystal substrate according to claim 1, wherein in the first step, a substrate in which an oxygen concentration of a plurality of the seed crystal substrates is respectively 1×10¹⁹ at/cm³ or less, is prepared as the substrate for crystal growth.

10. The method for manufacturing a nitride crystal substrate according to claim 1, wherein in the first step, a substrate in which an oxygen concentration of a plurality of the seed crystal substrates is respectively 3×10¹⁸ at/cm³ or less, is prepared as the substrate for crystal growth.

11. The method for manufacturing a nitride crystal substrate according to claim 9, wherein in the second step, an oxygen concentration of the crystal film is set to 1×10¹⁹ at/cm³ or less.

12. The method for manufacturing a nitride crystal substrate according to claim 10, wherein in the second step, an oxygen concentration of the crystal film is set to 3×10¹⁸ at/cm³ or less.

13. The method for manufacturing a nitride crystal substrate according to claim 1, wherein in the first step, a substrate in which all of a plurality of the seed crystal substrates are made of GaN crystals, and all main surfaces of them are composed of c-planes, and all lateral surfaces in contact with other seed crystal substrates are composed of a-planes only or are composed of M-planes only, is prepared as the substrate for crystal growth.

14. The method for manufacturing a nitride crystal substrate according to claim 1, wherein in the first step, a substrate in which a seed crystal substrate arbitrarily selected from a plurality of the seed crystal substrates is in contact with at least two or more other seed crystal substrates, is prepared as the substrate for crystal growth.

15. The method for manufacturing a nitride crystal substrate according to claim 1, wherein in the first step, a substrate in which two or more contact surfaces of a seed crystal substrate arbitrarily selected from a plurality of the seed crystal substrates are not orthogonal to each other, is prepared as the substrate for crystal growth.

16. The method for manufacturing a nitride crystal substrate according to claim 1, further comprising the steps of:
further growing a nitride crystal on the crystal film; and
cutting out a nitride crystal substrate from a growth layer of the nitride crystal.

17. The method for manufacturing a nitride crystal substrate according to claim 1, further comprising the steps of:
further growing a nitride crystal on the crystal film by a liquid-phase growth method;
further growing a nitride crystal on the nitride crystal grown by the liquid-phase growth method, by a vapor-phase growth method; and
cutting out a nitride crystal substrate from the nitride crystal layer grown by the vapor-phase growth method.

18. The method for manufacturing a nitride crystal substrate according to claim 1, further comprising the steps of:
further growing a nitride crystal on the crystal film by a liquid-phase growth method;
preparing a freestanding nitride crystal substrate by polishing front and back surfaces of the nitride crystal grown by the liquid-phase growth method;
further thickly growing a nitride crystal on the freestanding nitride crystal substrate by a vapor-phase growth method; and
cutting out a nitride crystal substrate from the nitride crystal layer grown by the vapor-phase growth method.

19. A substrate for crystal growth having a ground surface on which a nitride crystal is grown, comprising:
a plurality of seed crystal substrates made of nitride crystals, arranged in a planar appearance, so that their main surfaces are parallel to each other and their lateral surfaces are in contact with each other,
wherein a difference of a lattice constant between adjacent seed crystal substrates arbitrarily selected from a plurality of the seed crystal substrates is within 7×10⁻⁵ Å.

20. A substrate for crystal growth having a ground surface on which a nitride crystal is grown, comprising:
a plurality of seed crystal substrates made of nitride crystals, arranged in a planar appearance, so that their main surfaces are parallel to each other and their lateral surfaces are in contact with each other; and
a crystal film formed on a surface of a plurality of the seed crystal substrates arranged in a planar appearance, for combining the adjacent seed crystal substrates each other,
wherein a difference between a lattice constant of a seed crystal substrate arbitrarily selected from a plurality of the seed crystal substrates and a lattice constant of the crystal film is within 7×10⁻⁵ Å.
